(19) United States
(12) Patent Application Publication
(10) Pub. No.: US 2023/0369175 A1
(43) Pub. Date: Nov. 16, 2023

(54) POWER SEMICONDUCTOR MODULE ARRANGEMENT AND METHOD FOR PRODUCING THE SAME

(71) Applicant: Infineon Technologies AG, Neubiberg (DE)

(72) Inventors: Arthur Unrau, Geseke (DE); Matthias Droste, Arnsberg (DE); Achim Mücke, Erwitte (DE)

(21) Appl. No.: 18/144,464

(22) Filed: May 8, 2023

(30) Foreign Application Priority Data
May 16, 2022 (EP) 22173412.2

(51) Int. Cl. H01L 23/492; H01L 23/049; H01L 23/31; H01L 25/07; H01L 21/48

(52) U.S. Cl. CPC H01L 23/492; H01L 23/049; H01L 23/3107; H01L 25/072; H01L 21/4875

(57) ABSTRACT

A power semiconductor module arrangement includes: a base plate; substrates arranged on a first surface of the base plate; a connection layer arranged between a different one of the substrates and the base plate and permanently attaching the respective substrate to the base plate; and a spacer arranged between one of the substrates and the base plate and embedded in a material of the respective connection layer. For at least one substrate: either no spacer or one or more of a first kind of spacers having a first height in a vertical direction perpendicular to the first surface of the base plate is arranged below a first half of the respective substrate, and one or more of a second kind of spacers having a second height in the vertical direction is arranged below a second half of the respective substrate, the second height being greater than the first height.

### TECHNICAL FIELD

The instant disclosure relates to a power semiconductor module arrangement and to a method for producing the same.

### BACKGROUND

Power semiconductor module arrangements often include a base plate within a housing. At least one substrate is arranged on the base plate. A semiconductor arrangement including a plurality of controllable semiconductor elements (e.g., two IGBTs in a half-bridge configuration) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer is usually attached to the base plate by means of a solder layer or a sintering layer. When mounting the at least one substrate to the base plate, e.g., by soldering or sintering techniques, the substrates and base plate are under the influence of high temperatures, wherein the temperatures usually lie at about 250° C. or more, sometimes even at about 500° C. and more. The at least one substrate, the connection layer (e.g., solder layer), and the base plate usually have different CTEs (coefficients of thermal expansion). When heating, and subsequently cooling the different components during the assembly process, the difference between the CTEs of the different materials (e.g., copper, ceramic, solder) leads to a deformation of the base plate, usually a concave deflection in the direction of the surface on which the substrates are mounted.

When mounting the base plate to a heat sink, a connection layer (e.g., thermal interface material) is arranged between the base plate and the heat sink. Such a connection layer usually completely fills the space between the base plate and the heat sink and therefore has a non-uniform thickness because of the deflection of the base plate. Therefore, base plates are often pre-bent to have a convex deflection in the direction of the surface on which the substrates are mounted. With such a pre-bent base plate, the heating, and subsequent cooling of the different components during the assembly process results in an essentially flat base plate. However, this may result in uneven thicknesses of the resulting connection layers arranged between the substrates and the base plate, depending on the severity of the base plate's initial bow and on the position of the substrates on the base plate. Uneven connection layers may negatively affect the performance and reliability of the power semiconductor module arrangement.

There is a need for a power semiconductor module arrangement that avoids the drawbacks mentioned above as well as others and which has an increased performance and reliability, and for a method for producing such a power semiconductor module arrangement.

### SUMMARY

A power semiconductor module arrangement includes base plate, a plurality of substrates arranged on a first surface of the base plate, a plurality of connection layers, wherein each of the plurality of connection layers is arranged between a different one of the plurality of substrates and the base plate and permanently attaches the respective substrate to the base plate, and a plurality of spacers, wherein each of the plurality of spacers is arranged between one of the plurality of substrates and the base plate, and is embedded in the material of the respective connection layer, wherein for at least one of the plurality of substrates the following applies: either no spacer or one or more of a first kind of spacers having a first height in a vertical direction perpendicular to the first surface of the base plate is arranged below a first half of the respective substrate, and one or more of a second kind of spacers having a second height in the vertical direction is arranged below a second half of the respective substrate, wherein the second height is greater than the first height.

A base plate for a power semiconductor module includes a layer of a metallic material, and a plurality of spacers, the plurality of spacers comprising at least one of a first kind of spacers having a first height in a vertical direction perpendicular to a first surface of the layer of a metallic material, and at least one of a second kind of spacers having a second height in the vertical direction which is greater than the first height.

A method for forming a power semiconductor module arrangement includes arranging a plurality of substrates on a first surface of a base plate with a solid connection layer arranged between the base plate and each of the plurality of substrates, heating the base plate with the plurality of substrates and connection layers arranged thereon, thereby liquefying the material of the plurality of connection layers, and cooling the base plate with the plurality of substrates and connection layers arranged thereon, thereby solidifying the material of the plurality of connection layers, wherein for at least one of the plurality of substrates the following applies: either no spacer or one or more of a first kind of spacers having a first height in a vertical direction perpendicular to the first surface of the base plate is arranged below a first half of the respective substrate, and one or more of a second kind of spacers having a second height in the vertical direction is arranged below a second half of the respective substrate, wherein the second height is greater than the first height.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a power semiconductor module arrangement.

FIGS. 2A-2C illustrate cross-sectional views of a substrate and base plate during different steps of the process of mounting the substrate on the base plate.

FIG. 3 schematically illustrates a three-dimensional view of an exemplary pre-bent base plate.

FIGS. 4A-4C schematically illustrate cross-sectional views of a base plate and a plurality of substrates during different steps of the process of mounting the substrates on the base plate.

FIGS. 5A-5C schematically illustrate cross-sectional views of a base plate and a plurality of substrates according to one example during different steps of the process of mounting the substrates on the base plate.

FIG. 6 schematically illustrates a cross-sectional view of a base plate and a plurality of substrates mounted on the base plate according to an even further example.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description as well as in the claims, designations of certain elements as “first element”, “second element”, “third element” etc. are not to be understood as enumerative. Instead, such designations serve solely to address different “elements”. That is, e.g., the existence of a “third element” does not necessarily require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connectable pads and includes at least one semiconductor element with electrodes.

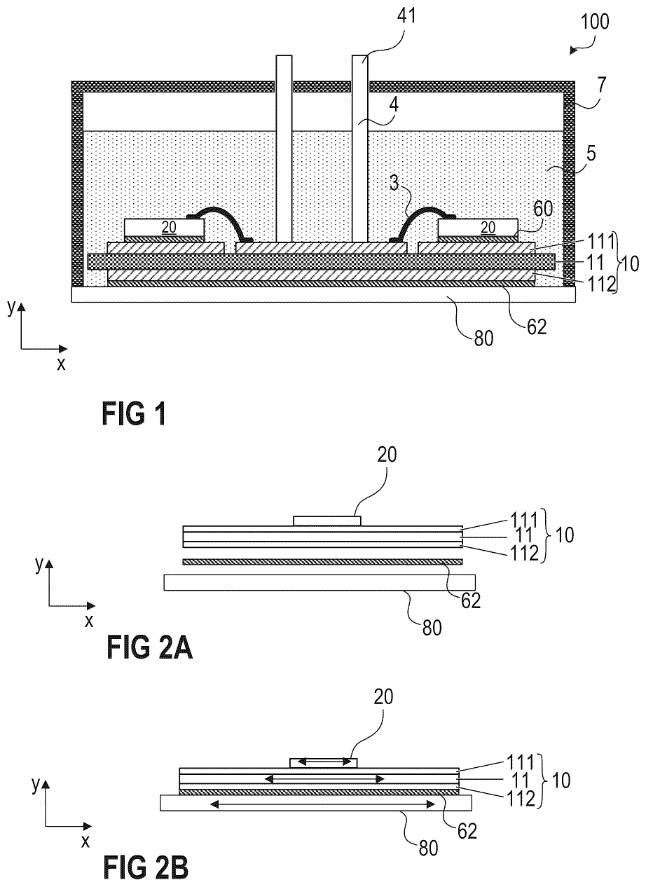

Referring to FIG. 1, a cross-sectional view of a power semiconductor module arrangement 100 is illustrated. The power semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. Alternatively, the dielectric insulation layer 11 may consist of an organic compound and include one or more of the following materials: Al₂O₃, AlN, SiC, BeO, BN, or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example The material of the dielectric insulation layer 11 may be filled with ceramic particles, for example. Such particles may comprise, e.g., SiO₂, Al₂O₃, AlN, SiN or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 may be arranged in a housing 7. In the example illustrated in FIG. 1, the substrate 10 is arranged on a base plate 80 which forms a ground surface of the housing 7, while the housing 7 itself solely comprises sidewalls and a cover. In some power semiconductor module arrangements 100, more than one substrate 10 is arranged on the same base plate 80 and within the same housing 7. The base plate 80 may comprise a layer of a metallic material such as, e.g., copper or AlSiC. Other materials, however, are also possible.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. According to another example, the second metallization layer 112 may be a structured layer. According to other examples, the second metallization layer 112 may be omitted altogether. The first metallization layer 111 is a structured layer in the example illustrated in FIG. 1. “Structured layer” in this context means that the respective metallization layer is not a continuous layer, but includes recesses between different sections of the layer. Such recesses are schematically illustrated in FIG. 1. The first metallization layer 111 in this example includes three different sections. Different semiconductor bodies 20 may be mounted to the same or to different sections of the first metallization layer 111. Different sections of the first metallization layer 111 may have no electrical connection or may be electrically connected to one or more other sections using electrical connections 3 such as, e.g., bonding wires. Semiconductor bodies 20 may be electrically connected to each other or to the first metallization layer 111 using electrical connections 3, for example. Electrical connections 3, instead of bonding wires, may also include bonding ribbons, connection plates or conductor rails, for example, to name just a few examples. The one or more semiconductor bodies 20 may be electrically and mechanically connected to the substrate 10 by an electrically conductive connection layer 60. Such an electrically conductive connection layer 60 may be a solder layer, a layer of an electrically conductive adhesive, or a layer of a sintered metal powder, e.g., a sintered silver (Ag) powder, for example.

The power semiconductor module arrangement 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end, while a second end 41 of the terminal elements 4 protrudes out of the housing 7. The terminal elements 4 may be electrically contacted from the outside at their second end 41. Such terminal elements 4, however, are only an example. The components inside the housing 7 may be electrically contacted from outside the housing 7 in any other suitable way. For example, terminal elements 4 may be arranged closer to or adjacent to the sidewalls of the housing 7. It is also possible that terminal elements 4 protrude vertically or horizontally through the sidewalls of the housing 7. It is even possible that terminal elements 4 protrude through a ground surface of the housing 7. The first end of a terminal element 4 may be electrically and mechanically connected to the substrate 10 by an electrically conductive connection layer, for example (not explicitly illustrated in FIG. 1). Such an electrically conductive connection layer may be a solder layer, a layer of an electrically conductive adhesive, or a layer of a sintered metal powder, e.g., a sintered silver (Ag) powder, for example. The first end of a terminal element 4 may also be electrically coupled to the substrate 10 via one or more electrical connections 3, for example.

The power semiconductor module arrangement 100 may further include an encapsulant 5. The encapsulant 5 may consist of or include a silicone gel or may be a rigid molding compound, for example. The encapsulant 5 may at least partly fill the interior of the housing 7, thereby covering the components and electrical connections that are arranged on the substrate 10. The terminal elements 4 may be partly embedded in the encapsulant 5. At least their second ends 41, however, are not covered by the encapsulant 5 and protrude from the encapsulant 5 through the housing 7 to the outside of the housing 7. The encapsulant 5 is configured to protect the components and electrical connections of the power semiconductor module 100, in particular the components arranged inside the housing 7, from certain environmental conditions and mechanical damage. It is generally also possible to omit the housing 7 and solely protect the substrate 10 and any components mounted thereon with an encapsulant 5. In this case, the encapsulant 5 may be a rigid material, for example.

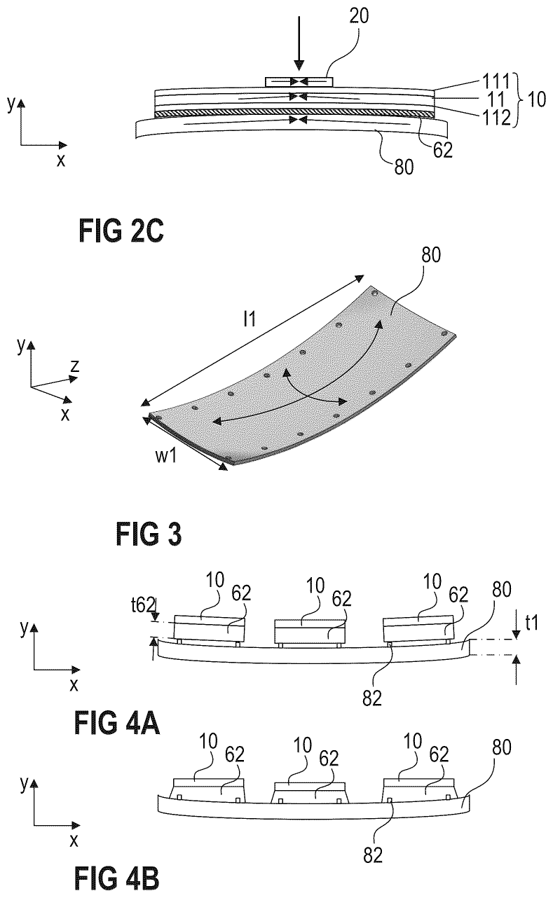

Now referring to FIGS. 2A-2C, a process of mounting a substrate 10 on a base plate 80 is schematically illustrated. The substrate 10 may be mechanically connected to the base plate 80 by a connection layer 62. That is, referring to FIG. 2A, a connection layer 62 may be arranged between the substrate 10 and the base plate 80. The connection layer 62 that is applied between the substrate 10 and the base plate 80 may be a metallic solder layer or a sintered layer, for example. These, however, are only examples. The connection layer 62 may comprise any other suitable material that is suitable to form a mechanical connection between the substrate 10 and the base plate 80.

When the substrate 10 is mounted on the base plate 80 (at least one semiconductor body 20 may already be mounted on the substrate 10 at this stage), the substrate 10, connection layer 62, and base plate 80 are heated up to high temperatures, causing each of these components, which each comprise different materials, to expand according to their individual coefficients of thermal expansion (CTE). This is schematically illustrated in FIG. 2B. During this process, the substrate 10 may be distorted. This is because the semiconductor body 20 and the substrate 10, which are rigidly bonded to one another, have different CTEs. Therefore, under the influence of high temperatures each of the components expands to a different extent, which is indicated with the different arrows in FIG. 2B. The components (i.e., substrate 10, connection layer 62, and base plate 80) are subsequently cooled down again, which results in a contraction of the different materials (indicated with the different arrows in FIG. 2C). The extent of the contraction also depends on the CTE of the materials. Therefore, after mounting a substrate 10 on an initially flat base plate 80, the base plate 80 often has a concave deflection in the direction of the surface on which the substrate 10 is mounted. This is schematically illustrated in FIG. 2C. The base plate 80 may be deflected in one direction in space only. However, the base plate 80 may also be deflected in two directions in space, resulting in a cushion-shape or shell-like shape of the base plate 80. The deflection of the base plate 80 or, in other words, the deviation from its original (essentially plane/flat) form, may be, e.g., between about 20 μm and about 2000 μm or even more (the deviation corresponds to the difference in height between the edges and the center of the base plate 80). In order to compensate the resulting deflection, base plates 80 are often pre-bent (before mounting the substrate 10 on the base plate 80) in a direction opposite to the direction of the resulting deflection. An exemplary pre-bent base plate 80 is schematically illustrated in the three-dimensional view of FIG. 3.

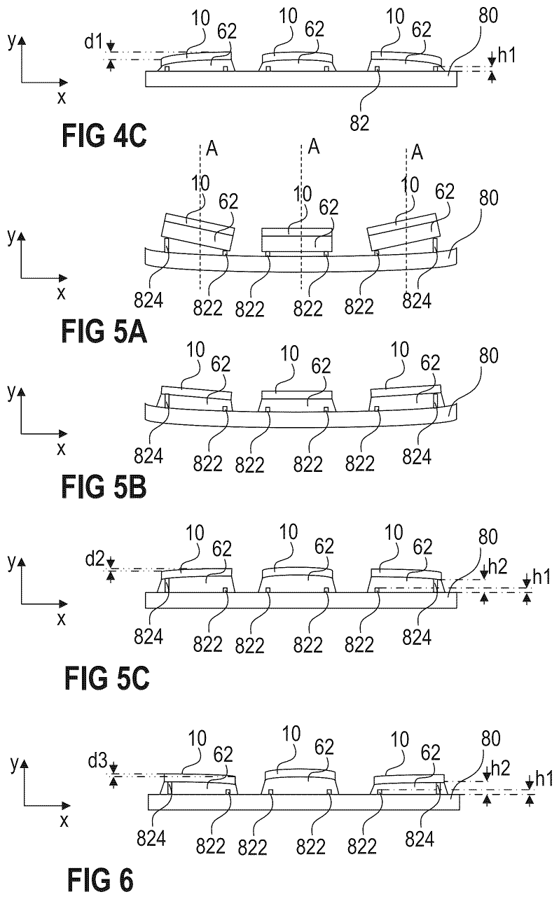

A cross-sectional view of a pre-bent base plate 80 is schematically illustrated in FIG. 4A. In a power semiconductor module, one or more substrates 10 are often arranged on a single base plate 80. The base plate 80 may have a thickness t1 in the vertical direction y of between about 1 mm and about 6 mm, for example. The base plate 80, however, may also be thinner than 1 mm or thicker than 6 mm. The base plate 80 may comprise a layer consisting of or including a metal or a metal matrix composite material (e.g., metal matrix composite MMC such as aluminum silicon carbide), for example. Suitable materials for a metal base plate 80 are, for example, copper, a copper alloy, aluminum, or an aluminum alloy. The base plate 80 may be coated by a thin coating layer (not illustrated). Such a coating layer may consist of or include nickel, silver, gold, or palladium, for example. The coating layer is optional and may improve the solderability of the base plate 80. The base plate 80 may have a rectangular form and have a width w1 of between 2 and 5 cm, and a length 11 of between 4 and 8 cm, for example. Other shapes and dimensions, however, are also possible.

A plurality of substrates 10 that is mounted on a base plate 80 is exemplarily illustrated in FIG. 4A. In particular, FIG. 4A schematically illustrates the pre-bent base plate 80 before soldering the substrates 10 to the base plate 80. Usually, a connection layer 62 is attached to each of the substrates 10. The connection layers 62 at this point are generally solid and have a uniform thickness t62 in the vertical direction y. The substrates 10 with the connection layers 62 attached thereto are positioned at their desired positions on the base plate 80. Depending on their position on the base plate 80, the substrates 10 may be slightly beveled (see, e.g., left and right substrates 10 of FIG. 4A) due to the deflection of the base plate 80. When the arrangement is subsequently heated, the connection layers 62 melt, which is schematically illustrated in FIG. 4B. Lying on the melted connection layers 62, the substrates 10 generally orient themselves horizontally, as the upper surface of the liquid solder tends to a horizontal orientation due to gravity. This results in an uneven thickness of the connection layers 62 due to the deflection of the base plate 80. For a substrate 10 arranged close to an edge of the base plate 80, for example, due to the curvature of the base plate 80, the connection layer 62 may have a greater thickness towards the center of the base plate 80. This is schematically illustrated for the outermost substrates 10 in FIG. 4B.

When the arrangement is subsequently cooled down again, due to the different CTEs of the different components, the base plate 80 deforms from its initially pre-bent form to an essentially flat form, similar to what has been described with respect to FIG. 2C above. The connection layers 62 solidify (harden) and remain in their uneven form (connection layers 62 have a non-uniform thickness), resulting in a deflection of the substrates 10, as is schematically illustrated in FIG. 4C. The uneven thickness of the connection layers 62 as well as the deflection of the substrates 10 may negatively affect the performance and reliability of the power semiconductor module arrangement.

In order to prevent the connection layers 62 of becoming too thin (less than a desired minimum thickness) during production, spacers 82 may be arranged between each of the substrates 10 and the base plate 80. Such spacers 82 are schematically illustrated in FIGS. 4A-4C. One or more spacers 82 may be arranged on the base plate 80, for example, before arranging the substrates 10 with the connection layers 62 thereon. The spacers 82 may be separate elements or may be integrally formed with the base plate 80. The spacers 82 may have any suitable form and may be arranged in any suitable positions on the base plate 80.

Usually, as few spacers 82 as possible are used, in order to save costs. According to one example, one spacer 82 is arranged below each corner of a rectangular semiconductor substrate 10. When joining the substrates 10 to the base plate 62 by means of the connection layers 62, the material forming the connection layers 62 is usually liquid or viscous during the heating step, as has been described above. The liquid or viscous material of the connection layers 62 may be displaced in the horizontal directions x, z to a certain degree and the thickness of the connection layers 62 may decrease, at least in some areas. The spacers 82 prevent the substrates 10 from moving closer to the base plate 80. However, due to the curvature of the base plate 80, it is possible that at least one side of a substrate 10 (e.g., a side which is closer to the center of the base plate 80) does not directly contact the respective spacers 82. This is, because a thickness of the resulting connection layer 62 may remain greater than a height hl of the respective spacer 82. The spacers 82 may remain between the substrates 10 and the base plate 80 after mounting/joining the substrates 10 onto the base plate 80. The spacers 82 may have a rounded or a square cross-section, for example. Any other cross-sections, however, are also possible. According to one example, the spacers 82 have an elongated form. That is, a length of a spacer 82 in a second horizontal direction z may be significantly larger than a width of the spacer 82 in a first horizontal direction x perpendicular to the second horizontal direction x. For example, one spacer 82 may extend along at least 50%, at least 75%, or even at least 90% of the length 11 or width w1 of a substrate 10. The number of spacers 82 as well as their shape and dimensions may depend on the size and shape of the respective substrate 10, for example.

In a conventional power semiconductor module arrangement as has been described with respect to FIGS. 4A-4C above, all of the spacers 82 have the same height hl above the base plate 80. This height hl is generally chosen to match the minimum desired thickness of the connection layer 62.

Now referring to the example illustrated in FIGS. 5A-5C, at least some of the spacers 82 have a greater height than others. That is, there may be at least two kinds of spacers 82. In the example illustrated in FIGS. 5A-5C the arrangement comprises a first kind of spacers 822, having a first height hl in the vertical direction y, and a second kind of spacers 824, having a second height h2 in the vertical direction y which is greater than the first height h1. According to one example, the second height h2 is between 20 μm and 500 μm greater than the first height h1.

As has been described above, at least some of a plurality of substrates 10 arranged on a base plate 80 may not even contact all of the respective spacers 82 after the heating step has been performed. As is schematically illustrated for the substrates 10 that are arranged closest to the edges of the base plate 80 where the curvature usually is more pronounced, such substrates 10 may not contact the spacers 822 that are arranged closer to a center of the base plate 80. That is, some of the spacers 822, due to the curvature of the base plate 80, may not be required at all, as the thickness of the connection layer 62 in the concerned areas is generally greater than the defined minimum thickness anyway. Therefore, it may also be possible to omit at least some of the first kind of spacers 822. Generally, the first height hl of a spacer of the first kind 822, therefore, may be between 0 and 400 μm, for example.

A second kind of spacers 824, which may be arranged closer to the edges of the base plate 80 has a second height h2 which is greater than the first height h1. The second height h2 of the second kind of spacers 824 may be chosen adequately in order to form a connection layer 62 having a more uniform thickness in the vertical direction y, as compared to the arrangement illustrated in FIGS. 4A-4C. In particular, the higher second kind of spacers 824 which are arranged closer to the edges of the base plate 80 prevent the respective substrates 10 from moving closer to the base plate 80. Therefore, while the material of the connection layers 62 is fluid during the heating step, the orientation of the respective substrates 10 may not be flat in a horizontal direction, but slightly beveled instead. This is schematically illustrated in FIG. 5B. When the arrangement is subsequently cooled down, the base plate 80 bends out of its initially curved shape to an essentially flat shape, resulting in an essentially flat orientation of the substrates 10. This is schematically illustrated in FIG. 5C.

The higher second kind of spacers 824 prevent one side of the respective substrates 10 to move closer to the base plate 80 than the other side of the substrate 10 with the first kind of spacers 822 arranged below.

Usually, at least one spacer 82 is arranged below a first half of a substrate 10, and at least one spacer 82 is arranged below a second half of the respective substrate 10. The first half and the second half of a substrate 10 may be defined by a plane A which divides the substrate 10 in two essentially similar halves, as is schematically illustrated in FIG. 5A. According to one example, for at least one substrate 10 of a power semiconductor module arrangement (left and right substrates 10 in the example of FIGS. 5A-5C), one or more spacers 822 of the first kind are arranged below a first half of a substrate 10 (between the first half of the substrate 10 and the base plate 80), and one or more spacers 824 of the second kind are arranged below a second half of the same substrate 10 (between the second half of the substrate 10 and the base plate 80), wherein the first half of the substrate 10 is arranged closer to the center of the base plate 80 as compared to the second half which is arranged closer to an edge of the base plate 80. The height h2 of the one or more second kind of spacers 824 may depend on their position with regard to the plane A. That is, if the one or more second kind of spacers 824 are arranged closer to the plane A (closer to the center of the substrate 10), their height h2 may be chosen to be greater. If the one or more second kind of spacers 824 are arranged further away from the plane A (closer to the edge of the substrate 10), their height h2 may be chosen to be somewhat smaller. In any case, however, the height h2 of the one or more second kind of spacers 824 is greater than the height hl of the one or more first kind of spacers 822. As has been described above, it is also possible to omit the first kind of spacers 822 for at least one of the substrates 10. That is, no spacer at all may be arranged below the first half of the respective substrate 10, while one or more of the second kind of spacers 824 are arranged below the second half of the respective substrate 10.

If an uneven number of substrates 10 is arranged on a base plate 80, for example, there may be one substrate 10 which is arranged essentially at the center of the base plate 80 (middle substrate 10 in the example of FIGS. 5A-5C). Only spacers 822 of the first kind and no spacers 824 of the second kind may be arranged below such substrates 10, as is schematically illustrated for the middle substrate 10 in FIGS. 5A-5C. This is because such substrates 10 are generally not prone to the problems described with respect to FIGS. 4A-4C above, because the curvature of the base plate 80 below the first half of the respective substrate 10 is generally symmetric to the curvature below the second half of the respective substrate 10.

By choosing the height h2 of the one or more second kind of spacers 824 it is possible to adjust the resulting orientation of the respective substrates 10. If, for example, the second height h2 is 200 μm and the first height h1 is at least 20 μm less than the second height h2, this may result in a still slightly beveled substrate 10, as is schematically illustrated in FIG. 5C. In particular, the first half of the substrate 10, after cooling down the arrangement, may be slightly higher above the first surface of the base plate 80 as compared to the second half. A difference in height d2 between the two outermost edges of the respective substrate 10 may be between 50 and 100 μm, for example. This difference in height d2 is significantly reduced as compared to the difference in height d1 resulting in the arrangement of FIGS. 4A-4C (see, e.g., FIG. 4C). A tilt, however, still remains. If the second height h2 is increased further to, e.g., 250 μm, the resulting difference in height d2 may be essentially zero. By increasing the second height h2 even further, e.g., to 300 μm or more, this may result in a tilt in the other direction. That is, the second half of the substrate 10, after cooling down the arrangement, may be slightly higher above the first surface of the base plate 80 as compared to the first half. This may result in a difference in height d3 between the two outermost edges of the respective substrate 10 of between −50 and −150 μm, for example (negative tilt values due to the different direction of the tilt). This is schematically illustrated in FIG. 6. The values of the second height h2 of 200 μm, 250 μm and 300 μm are merely examples. The specific values and the resulting differences in height dx depend on the dimensions and positions of the substrates 10 as well as on the dimensions and curvature of the base plate 80.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor module arrangement, comprising:
a base plate;
a plurality of substrates arranged on a first surface of the base plate;
a plurality of connection layers, wherein each of the plurality of connection layers is arranged between a different one of the plurality of substrates and the base plate and permanently attaches the respective substrate to the base plate; and
a plurality of spacers, wherein each of the plurality of spacers is arranged between one of the plurality of substrates and the base plate, and is embedded in a material of the respective connection layer,
wherein for at least one of the plurality of substrates:
either no spacer or one or more of a first kind of spacers having a first height in a vertical direction perpendicular to the first surface of the base plate is arranged below a first half of the respective substrate; and
one or more of a second kind of spacers having a second height in the vertical direction is arranged below a second half of the respective substrate, the second height being greater than the first height.

2. The power semiconductor module arrangement of claim 1, wherein one or more of the first kind of spacers is arranged below the first half of the respective substrate, and wherein the second height is between 20 μm and 500 μm greater than the first height.

3. The power semiconductor module arrangement of claim 1, wherein each of the one or more of the first kind of spacers has a first height of between 0 μm and 400 μm.

4. The power semiconductor module arrangement of claim 1, wherein each of the one or more second kind of spacers has a second height of between 20 μm and 900 μm.

5. The power semiconductor module arrangement of claim 1, wherein the second half of the respective substrate is arranged closer to an edge of the base plate than the first half of the same substrate.

6. The power semiconductor module arrangement of claim 1, wherein the base plate is flat.

7. The power semiconductor module arrangement of claim 1, wherein the base plate comprises a layer of metallic material.

8. The power semiconductor module arrangement of claim 1, further comprising at least one semiconductor body arranged on a top surface of each of the plurality of substrates, and wherein the top surface of a substrate is a surface facing away from the base plate.

9. The power semiconductor module arrangement of claim 1, wherein the plurality of connection layers are solder layers.

10. A base plate for a power semiconductor module, the base plate comprising:
a layer of a metallic material; and
a plurality of spacers, the plurality of spacers comprising at least one of a first kind of spacers having a first height in a vertical direction perpendicular to a first surface of the layer of a metallic material, and at least one of a second kind of spacers having a second height in the vertical direction which is greater than the first height.

11. The base plate of claim 10, wherein the layer of metallic material has a convex deflection.

12. A method for forming a power semiconductor module arrangement, the method comprising:
arranging a plurality of substrates on a first surface of a base plate with a solid connection layer arranged between the base plate and each of the plurality of substrates;
heating the base plate with the plurality of substrates and connection layers arranged thereon, thereby liquefying a material of the plurality of connection layers; and
cooling the base plate with the plurality of substrates and connection layers arranged thereon, thereby solidifying the material of the plurality of connection layers,
wherein for at least one of the plurality of substrates:
either no spacer or one or more of a first kind of spacers having a first height in a vertical direction perpendicular to the first surface of the base plate is arranged below a first half of the respective substrate; and
one or more of a second kind of spacers having a second height in the vertical direction is arranged below a second half of the respective substrate, the second height being greater than the first height.

13. The method of claim 12, wherein before the heating of the base plate, the base plate has a convex form, and wherein during the cooling of the base plate, the base plate deforms from the convex form to a flat form.
